(19) United States
(12) Patent Application Publication
(10) Pub. No.: US 2018/0164002 A1
(43) Pub. Date: Jun. 14, 2018

(54) THERMOELECTRIC MODULE WITH TEMPORARILY COMPRESSIBLE COMPRESSION LIMITER FOR VEHICLE BATTERY

(71) Applicant: Gentherm Inc., Northville, MI (US)

(72) Inventors: Rüdiger Spillner, Augsburg (DE); Dumitru-Cristian Leu, Freising (DE)

(21) Appl. No.: 15/580,518

(22) PCT Filed: Jun. 8, 2016
(86) PCT No.: PCT/US2016/036437

§ 371 Date: Dec. 7, 2017

Related U.S. Application Data
(60) Provisional application No. 62/173,485, filed on Jun. 10, 2015.

(51) Int. Cl. F25B 21/04; H01L 35/06; H01L 35/32; H01L 35/34; H01M 10/613; H01M 10/625; H01M 10/6572

(52) U.S. Cl. CPC F25B 21/04; H01L 35/06; H01L 35/32; H01L 35/34; H01M 10/0525; H01M 10/625; H01M 10/6572; H01M 2220/20; H01M 10/613

(57) ABSTRACT

A thermoelectric module assembly for thermally conditioning a component includes first and second members that are spaced apart from one another and are configured to respectively provide cold and hot sides. An insulator plate is arranged between the first and second members. A thermoelectric device is arranged within the insulator plate and is operatively engaged with the first and second members. A fastening element secures the first and second members to one another about the insulator plate in an assembled condition. The fastening element includes a temporarily compressible material that provides a compression limiter.

### CROSS-REFERENCE TO RELATED APPLICATIONS

This application claims priority to U.S. Provisional Application No. 62/173,485, which was filed on Jun. 10, 2015 and is incorporated herein by reference.

### BACKGROUND

This disclosure relates to a thermoelectric module used to cool a vehicle component, such as a battery. In particular, the disclosure relates to a compression limiter configuration to improve heat transfer efficiency.

Lithium ion batteries are used in passenger and other types of vehicles to provide power to electric motors that provide propulsion to the vehicle. Such batteries can generate a significant amount of heat such that the battery must be cooled to prevent performance degradation.

One type of vehicle battery cooling arrangement that has been proposed that includes a thermoelectric module arranged beneath the battery and adjacent to a cold plate assembly. The thermoelectric module includes thermoelectric devices that operate based upon the Peltier effect to provide cooling adjacent to the battery. Heat transferred through the thermoelectric device is rejected to the cold plate assembly, which may have a cooling fluid circulated therethrough and sent to a heat exchanger.

It is desirable to design the thermoelectric module so as to efficiently transfer heat through some components within the thermoelectric module while insulating other components within the thermoelectric module.

### SUMMARY

In one exemplary embodiment, a thermoelectric module assembly for thermally conditioning a component includes first and second members that are spaced apart from one another and are configured to respectively provide cold and hot sides. An insulator plate is arranged between the first and second members. A thermoelectric device is arranged within the insulator plate and is operatively engaged with the first and second members. A fastening element secures the first and second members to one another about the insulator plate in an assembled condition. The fastening element includes a temporarily compressible material that provides a compression limiter.

In a further embodiment of the above, the temporarily compressible material includes a liquid state in the assembled condition and a cured state in the assembled condition. The temporarily compressible material in the cured state is configured to inhibit movement between the first and second members to a greater degree than the temporarily compressible material in the liquid state.

In a further embodiment of any of the above, the temporarily compressible material is an epoxy.

In a further embodiment of any of the above, the temporarily compressible material is an RTV.

In a further embodiment of any of the above, the fastening element includes a threaded fastener that clamps the first and second members about the thermoelectric device to provide a clamp load in the assembled condition.

In a further embodiment of any of the above, the temporarily compressible material clamps the first and second members about the thermoelectric device to provide a clamp load in the assembled condition without threaded fasteners.

In a further embodiment of any of the above, the first and second members are metallic and the insulator plate is a plastic.

In a further embodiment of any of the above, the second heat member includes a raised pad supporting the thermoelectric device.

In a further embodiment of any of the above, a thermal foil is arranged between and in engagement with the pad and the thermoelectric device.

In a further embodiment of any of the above, the thermoelectric device is a Peltier device.

In a further embodiment of any of the above, the second member includes a protrusion that cooperates with the insulator plate to laterally locate the insulator plate and the second member relative to one another. The temporarily compressible material is provided on the protrusion.

In a further embodiment of any of the above, the fastening element includes a threaded fastener that is secured to a threaded inner diameter of the protrusion.

In a further embodiment of any of the above, the insulator plate has at least four discrete protrusions that surround the thermoelectric device.

In a further embodiment of any of the above, the first and second members are first and second heat spreaders. The first and second heat spreaders and the insulator plate are secured to one another to provide the thermoelectric module assembly.

In a further embodiment of any of the above, the first member provides a heat spreader and the second member provides a cold plate assembly. The cold plate assembly includes cooling passages that are configured to receive a coolant circulated through the cooling passages.

In another exemplary embodiment, a method of manufacturing a thermoelectric module assembly includes the step of providing a temporarily compressible material between first and second members. The first and second members are clamped about a thermoelectric device to provide a clamp load on the thermoelectric device. The temporarily compressible material is solidified while maintaining the clamp load.

In a further embodiment of any of the above, the temporarily compressible material includes a liquid state and a cured state under the clamp load.

In a further embodiment of any of the above, the clamping step includes tightening threaded fasteners to secure the first and second members to one another.

In a further embodiment of any of the above, the solidified temporarily compressible material limits compression of the thermoelectric device under a battery load.

In a further embodiment of any of the above, the temporarily compressible material maintains the clamp load subsequent to the clamping step.

### BRIEF DESCRIPTION OF THE DRAWINGS

The disclosure can be further understood by reference to the following detailed description when considered in connection with the accompanying drawings wherein:

FIG. 1A is a highly schematic view of a vehicle with a vehicle system temperature regulated by a cooling system.

FIG. 1B illustrates a cooling system that includes a thermoelectric module assembly and a cold plate assembly.

FIG. 2 is an exploded perspective view of a thermoelectric module assembly.

FIG. 3A is a perspective view of the insulator plate mounted to a heat spreader.

FIG. 3B is a perspective view of the insulator plate and heat spreader shown in FIG. 3A with thermoelectric devices arranged within the insulator plate.

FIG. 4 is a perspective view of the thermoelectric module assembly.

FIG. 5 is a cross-sectional view of one thermoelectric module assembly.

FIG. 6 is a cross-sectional view of another thermoelectric module assembly.

FIG. 7A is a schematic view of an assembly procedure using a temporarily compressible compression limiter.

FIG. 7B is a schematic view of the thermoelectric module assembly subsequent to the assembly procedure shown in FIG. 7A.

The embodiments, examples and alternatives of the preceding paragraphs, the claims, or the following description and drawings, including any of their various aspects or respective individual features, may be taken independently or in any combination. Features described in connection with one embodiment are applicable to all embodiments, unless such features are incompatible.

### DETAILED DESCRIPTION

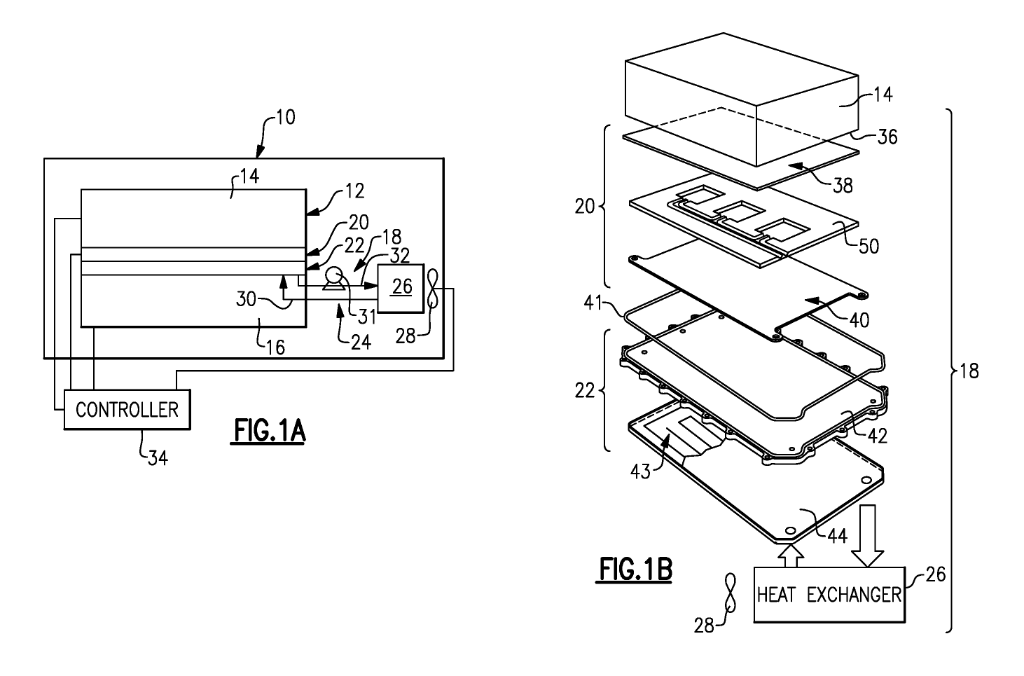

A vehicle 10 is schematically illustrated in FIG. 1A. The vehicle 10 includes a vehicle system 12 that either needs to be heated or cooled. In one example, the vehicle system 12 includes a battery 14, such as a lithium ion battery used for vehicle propulsion that generates a significant amount of heat. Such a battery must be cooled during operation otherwise the battery efficiency and/or integrity may degrade.

A cooling system 18 is arranged between the battery 14 and a DC/DC converter 16 in a stack to remove heat from the battery 14 thus cooling the vehicle system 12. The DC/DC converter 16 provides an electrical interface between the battery 14 and the vehicle electrics. A cooling system 18 includes a thermoelectric module assembly 20 mounted to a cold plate assembly 22 that is in communication with a cooling loop 24. A cooling fluid, such as glycol, is circulated by a pump 31 within the cooling loop 24. Heat is rejected to the coolant via the cold plate assembly 22 through supply and return coolant lines 30, 32 that are connected to a heat exchanger 26. A fan or blower 28 may be used to remove heat from the coolant within the heat exchanger 26 to an ambient environment, for example.

A controller 34 communicates with various components of the vehicle 10, vehicle system 12 and cooling system 18 to coordinate battery cooling. Sensors and outputs (not shown) may be connected to the controller 34.

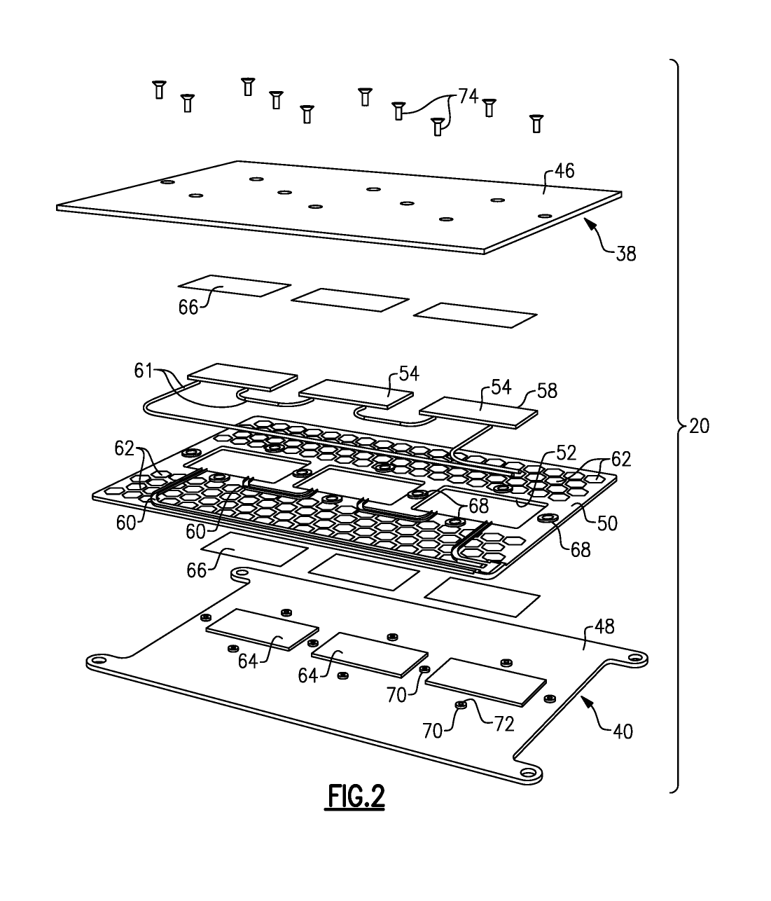

An example cooling system 18 is shown in more detail in FIG. 1B. The thermoelectric module assembly 20 includes a cold side 38 that supports a surface 36 of the battery 14. An insulator plate 50, which is constructed from a plastic, carries thermoelectric devices (shown at 58 in FIG. 2) and separates the cold side 38 (at the battery 14) from a hot side 40 (at the cold plate assembly 22).

The cold plate assembly 22 includes first and second cold plates 42, 44 secured to one another to enclose a network of fluid passages 43 that communicate coolant across the cold plate assembly 22 to receive heat rejected from the hot side 40. A seal 41 may be provided between the thermoelectric module assembly 20 and the cold plate assembly 22. The heated coolant is transferred to the heat exchanger 26, which may be located remotely from the stack.

Referring to FIG. 2, an example thermoelectric module assembly 20 is shown in more detail. The cold and hot sides 38, 40 are respectively provided by first and second heat spreaders 46, 48, constructed from metal. The insulator plate 50 is sandwiched between the first and second heat spreaders 46, 48 once assembled into a single unit that can be secured to the cold plate assembly 22.

The insulator plate 50 includes apertures 52 within which thermoelectric devices 54 are arranged. In the example, the thermoelectric devices utilize the Peltier effect to provide a cold side adjacent to the first heat spreader 46 and a hot side adjacent to the second heat spreader 48.

Insulator plate 50 includes formed wire channels 60 that receive wires 61 of the thermoelectric devices 54 of the thermoelectric module assembly 20. In the example, three Peltier devices are wired in series with one another.

A matrix of voids 62 is provided in the insulator plate 50 to reduce the thermal mass of the insulator plate 50 and provide air gaps that insulate the first and second heat spreaders 46, 48 from one another. The voids 62 may be any suitable size, shape or pattern. The voids may be deep recesses relative to the thickness of the insulator plate 50 (shown) or extend all the way through the insulator plate 50.

The second heat spreader 48 includes raised pads 64 that extend upward toward the insulator plate 50 to support the thermoelectric devices 54. Thermal foils 66 may be provided between the thermoelectric devices 54 and the first and second heat spreaders 46, 48 to ensure adequate engagement between the components for thermal efficiency.

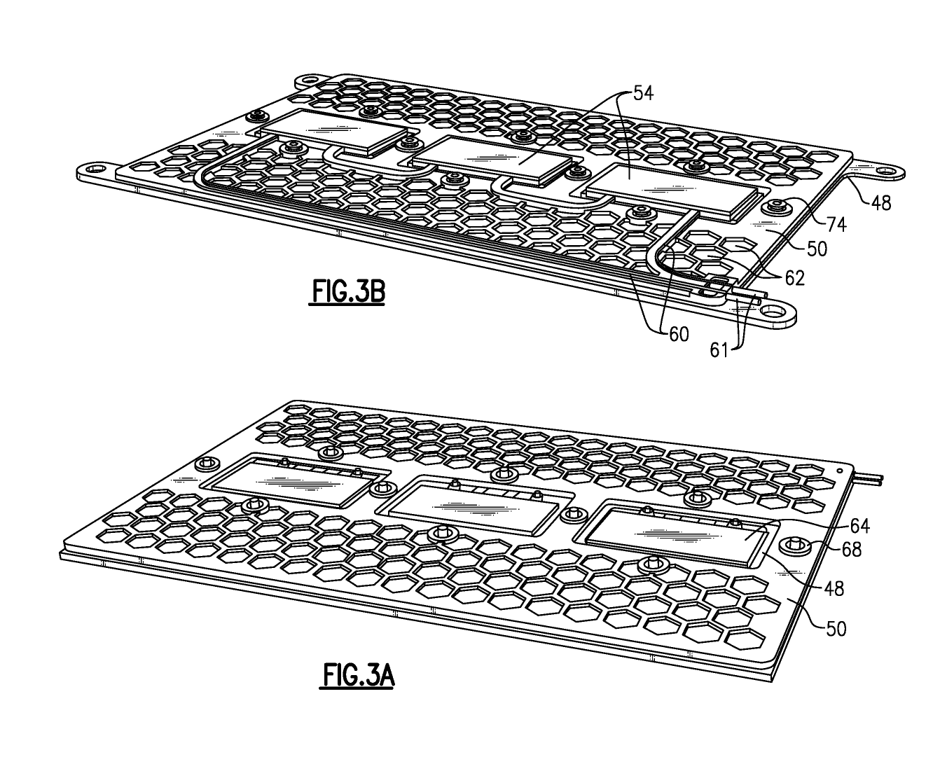

Referring to FIGS. 2 and 3A-3B, the insulator plate 50 includes spacers 68, which can be used to locate the insulator plate 50 with respect to the first and second heat spreaders 46, 48. Protrusions 70 may be provided on, for example, the second heat spreader 48 to locate the insulator plate 50 relative to the second heat spreader 48 during assembly.

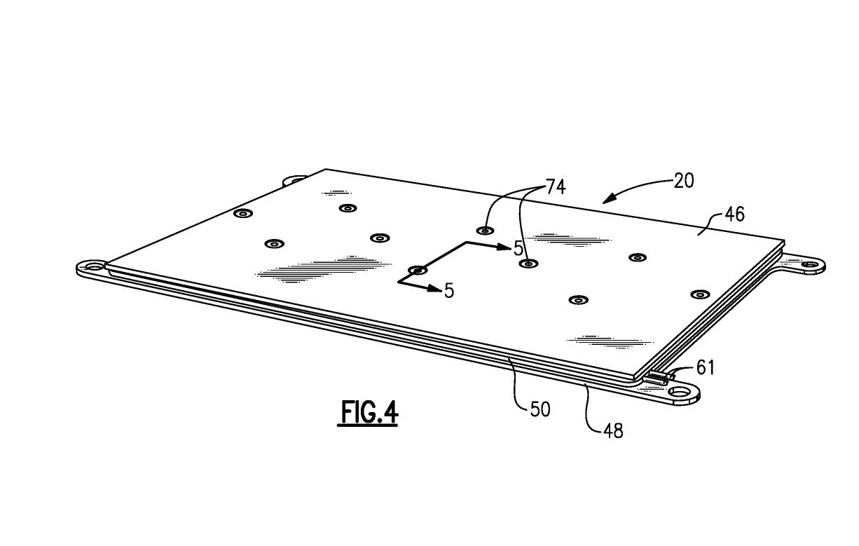

It is desirable to maintain a predetermined clamp load on the thermoelectric device 54 to ensure sufficient engagement and thermal transfer between the thermoelectric device 54 and adjacent components in the stack. However, the load on the thermoelectric device 54 must be limited, in particular under the weight of the battery 14, to prevent damage to the thermoelectric device 54. To this end, a temporarily compressible material 94 (FIGS. 5 and 6) is provided between the first and second heat spreaders 46, 48. The temporarily compressible material 94 is relatively compressible in a liquid state, but substantially comparably rigid in a cured state. In this manner, a tolerance stack-up between components can be accommodated during assembly by the liquid/uncured temporarily compressible material 94, and then once cured the temporarily compressible material 94 becomes rigid, thus preventing overloading of the thermoelectric device 54 under the weight of the battery 14.

Referring to FIGS. 4 and 5, the thermoelectric device 54 is sandwiched between first and second members in the thermoelectric module assembly 20, which, in the example, all provided by the first and second heat spreaders 46, 48. The protrusion 70 does not extend the entire distance to the first heat spreader 46 to accommodate a tolerance stack-up between the components of the thermoelectric module assembly 20. In the example, the insulator plate 50 has a first thickness, and the protrusion 70 has a second thickness that is less than the first thickness. The temporarily compressible material 94, such as a RTV silicone or an epoxy, for example, is applied to an end of the protrusion 70 and engages an underside of the first heat spreader 46. A desired viscosity is selected to maintain sufficient material on the protrusion 70 during curing. The cured compressible material makes up the difference between the first and second thicknesses. A glue, plastic, soldering tin or other material may be used.

In the example, fastening elements such as fasteners 74 extend through holes in the first heat spreader 46 and are received within threaded inner diameters 72 of the protrusions 70 to secure the stack of first and second heat spreaders 46, 48 and the insulator plate 50. The temporarily compressible material 94 circumscribes its respective fastener 74 in the example. As such, it may be desirable to secure the fasteners 74 to the second heat spreader 48 prior to temporarily compressible material 94 curing. The fasteners 74 are tightened to a predetermined torque to a desired clamp load while the temporarily compressible material 94 is still uncured. The temporarily compressible material 94 is then allowed to cure or solidify before the battery 14 is mounted to the thermoelectric module 20, becoming rigid such that movement between the first and second heat spreaders 46, 48 is inhibited to a greater degree than the temporarily compressible material 94 when in the liquid state.

Since the temporarily compressible material 94 can accommodate a variation in component tolerances, the thermal foils 66 can be eliminated or thinner foils used.

As shown in FIG. 6, the second heat spreader 48 can be eliminated and the first heat spreader 46 can be secured to the cold plate assembly 22. The temporarily compressible material 94 is used in the same manner as described above with respect to FIGS. 4 and 5.

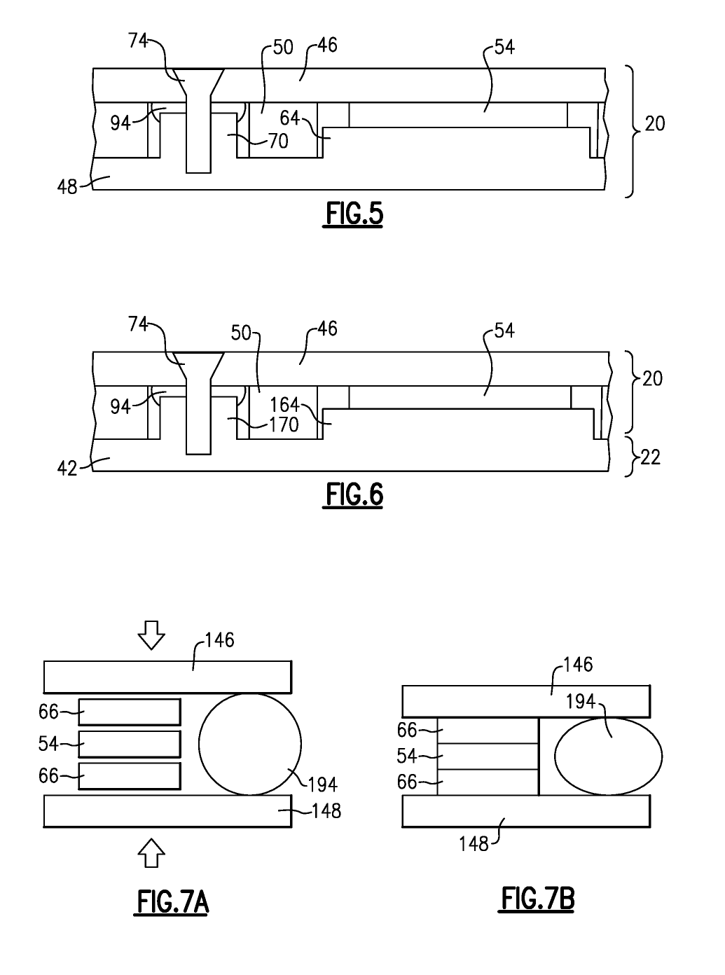

In the example shown in FIGS. 7A and 7B, the fasteners 74 can be eliminated and the temporarily compressible material 194 used to secure the first and second heat spreaders 146, 148. In such an arrangement, an assembly load (opposing arrows in FIG. 6) is maintained on the thermoelectric module assembly 120, with the desired clamp load applied to the thermoelectric device 54, until the temporarily compressible material 194 cures. The assembly load can then be removed, and the clamp load is maintained by the cured temporarily compressible material 194 adhering to the first and second load spreaders 146, 148 to one another.

In operation, the temporarily compressible material 94 prevents the battery 14 from overloading the thermoelectric device 54 under the battery's weight. An undesired battery temperature is detected by the controller 34. The thermoelectric devices 50 are powered to produce a cold side of the thermoelectric device 54 that is transferred to the first heat spreader 46 adjacent to the battery 14 increasing the temperature differential between these components and increasing the heat transfer therebetween. Heat from the battery is transferred from the first heat spreader 46 through the thermoelectric device 54 to the second heat spreader 48. However, the isolator plate 50 acts to prevent heat from being transmitted from the first heat spreader 46 to the second heat spreader 48. The second heat spreader 48 rejects heat to the coolant within the cold plate assembly 22. Coolant is circulated from the cold plate assembly 22 to the heat exchanger 26, which rejects heat to the ambient environment, and this heat transfer rate may be increased by use of the blower 28.

It should be understood that although a particular component arrangement is disclosed in the illustrated embodiment, other arrangements will benefit herefrom. Although particular step sequences are shown, described, and claimed, it also should be understood that steps may be performed in any order, separated or combined unless otherwise indicated and will still benefit from the present invention.

Although the different examples have specific components shown in the illustrations, embodiments of this invention are not limited to those particular combinations. It is possible to use some of the components or features from one of the examples in combination with features or components from another one of the examples.

Although an example embodiment has been disclosed, a worker of ordinary skill in this art would recognize that certain modifications would come within the scope of the claims. For that reason, the following claims should be studied to determine their true scope and content.

What is claimed is:

1. A thermoelectric module assembly for thermally conditioning a component, the assembly comprising:
first and second members are spaced apart from one another and are configured to respectively provide cold and hot sides;
an insulator plate is arranged between the first and second members;
a thermoelectric device is arranged within the insulator plate and is operatively engaged with the first and second members;
a fastening element secures the first and second members to one another about the insulator plate in an assembled condition, wherein the fastening element includes a temporarily compressible material providing a compression limiter.

2. The assembly according to claim 1, wherein the temporarily compressible material includes a liquid state in the assembled condition and a cured state in the assembled condition, the temporarily compressible material in the cured state configured to inhibit movement between the first and second members to a greater degree than the temporarily compressible material in the liquid state.

3. The assembly according to claim 2, wherein the temporarily compressible material is an epoxy.

4. The assembly according to claim 2, wherein the temporarily compressible material is an RTV.

5. The assembly according to claim 1, wherein the fastening element includes a threaded fastener that clamps the first and second members about the thermoelectric device to provide a clamp load in the assembled condition.

6. The assembly according to claim 1, wherein the temporarily compressible material clamps the first and second members about the thermoelectric device to provide a clamp load in the assembled condition without threaded fasteners.

7. The assembly according to claim 1, wherein the first and second members are metallic and the insulator plate is a plastic.

8. The assembly according to claim 1, wherein the second heat member includes a raised pad supporting the thermoelectric device.

9. The assembly according to claim 8, comprising a thermal foil arranged between and in engagement with the pad and the thermoelectric device.

10. The assembly according to claim 8, wherein the thermoelectric device is a Peltier device.

11. The assembly according to claim 1, wherein the second member includes a protrusion that cooperates with the insulator plate to laterally locate the insulator plate and the second member relative to one another, the temporarily compressible material provided on the protrusion.

12. The assembly according to claim 11, wherein the fastening element includes a threaded fastener secured to a threaded inner diameter of the protrusion.

13. The assembly according to claim 11, wherein the insulator plate has at least four discrete protrusions that surround the thermoelectric device.

14. The assembly according to claim 1, wherein the first and second members are first and second heat spreaders, the first and second heat spreaders and the insulator plate secured to one another to provide the thermoelectric module assembly.

15. The assembly according to claim 1, wherein the first member provides a heat spreader and the second member provides a cold plate assembly, the cold plate assembly includes cooling passages configured to receive a coolant circulated through the cooling passages.

16. A method of manufacturing a thermoelectric module assembly comprising the steps of:
providing a temporarily compressible material between first and second members;
clamping the first and second members about a thermoelectric device to provide a clamp load on the thermoelectric device; and
solidifying the temporarily compressible material while maintaining the clamp load.

17. The method according to claim 16, wherein the temporarily compressible material includes a liquid state and a cured state under the clamp load.

18. The method according to claim 16, wherein the clamping step includes tightening threaded fasteners to secure the first and second members to one another.

19. The method according to claim 16, wherein the solidified temporarily compressible material limits compression of the thermoelectric device under a battery load.

20. The method according to claim 16, wherein the temporarily compressible material maintains the clamp load subsequent to the clamping step.
